(19) United States
(12) Patent Application Publication
(10) Pub. No.: US 2025/0221257 A1
(43) Pub. Date: Jul. 3, 2025

(54) DISPLAY DEVICE

(71) Applicant: LG Display Co., Ltd., Seoul (KR)

(72) Inventor: DongHun Jung, Paju-si (KR)

(73) Assignee: LG Display Co., Ltd., Seoul (KR)

(21) Appl. No.: 18/795,961

(22) Filed: Aug. 6, 2024

(30) Foreign Application Priority Data
Dec. 28, 2023 (KR) 10-2023-0195451

(51) Int. Cl. H10K 59/80; H10K 59/40

(52) U.S. Cl. CPC H10K 59/873; H10K 59/40

(57) ABSTRACT

A display device includes a substrate including a display area where subpixels are disposed and a non-display area located outside the display area, and having a first groove in the non-display area; a first inorganic layer disposed on the substrate, extending from the display area to the non-display area, and having a second groove which is located in the non-display area to be closer to the display area than the first groove; an organic layer disposed on a portion of the first inorganic layer in the non-display area, and filling the second groove; a second inorganic layer extending from the display area to the non-display area, disposed on the first inorganic layer to cover the organic layer, and extending into the first groove; and a third inorganic layer extending from the display area to the non-display area, disposed on the second inorganic layer, and extending into the first groove.

### CROSS-REFERENCE TO RELATED APPLICATION

This application claims priority from Korean Patent Application No. 10-2023-0195451, filed on Dec. 28, 2023, which is hereby incorporated by reference for all purposes as if fully set forth herein.

### BACKGROUND

### Field

Embodiments of the present disclosure relate to a display device.

### Description of Related Art

The display panel of a display device may include a display area where an image is displayed and a non-display area where an image is not displayed. Various structures, circuits and interconnections may be disposed in the non-display area (also referred to as a “bezel”) of the display panel. Due to this fact, it is not easy to reduce the bezel of the display panel.

In addition, when the display panel is designed to reduce the bezel, the possibility of a crack to occur in the display panel increases, which may lead to moisture penetration and result in a panel defect.

### SUMMARY

Embodiments of the present disclosure may provide a display device which can prevent moisture penetration while enabling a narrow bezel.

Embodiments of the present disclosure may provide a display device which can prevent a layer lifting phenomenon while enabling a narrow bezel.

A display device according to embodiments of the present disclosure may include a substrate including a display area in which a plurality of subpixels are disposed and a non-display area which is located outside the display area and includes a pad area, and having a first groove in the non-display area; a first inorganic layer disposed on the substrate, extending from the display area to the non-display area, and having a second groove which is located in the non-display area to be closer to the display area than the first groove; an organic layer disposed on a portion of the first inorganic layer in the non-display area, and filling the second groove; a second inorganic layer extending from the display area to the non-display area, disposed on the first inorganic layer to cover the organic layer, and extending to the inside of the first groove; and a third inorganic layer extending from the display area to the non-display area, disposed on the second inorganic layer, and extending to the inside of the first groove.

The display device according to the embodiments of the present disclosure may further include a touch insulating layer extending from the display area to the non-display area, disposed on the third inorganic layer, and overlapping the organic layer.

The first inorganic layer may include at least one inorganic layer for forming a transistor.

The display device according to the embodiments of the present disclosure may further include a light emitting element disposed between the first inorganic layer and the second inorganic layer in the display area; and an encapsulation layer on the light emitting element. The second inorganic layer and the third inorganic layer may be included in the encapsulation layer.

In the display device according to the embodiments of the present disclosure, the first inorganic layer may include a first insulating layer on the substrate; and a second insulating layer on the first insulating layer. The second groove may correspond to a hole which is formed in the second insulating layer.

The display device according to the embodiments of the present disclosure may further include a blocking metal disposed on the first insulating layer.

Both ends of the blocking metal may be located between the first insulating layer and the second insulating layer, and a portion between both the ends of the blocking metal may overlap the second groove.

A display device according to embodiments of the present disclosure may include substrate including a display area in which an image is displayed and a non-display area as an area outside the display area, and having a first groove in the non-display area; a first inorganic layer disposed on the substrate, extending from the display area to the non-display area, and having a second groove which is located in the non-display area to be closer to the display area than the first groove; a planarization layer on the first inorganic layer; an organic layer disposed on a portion of the first inorganic layer in the non-display area, and filling the second groove; a light emitting element on the planarization layer; a first inorganic encapsulation layer (corresponding to the second inorganic layer described above) on the light emitting element; an organic encapsulation layer on the first inorganic encapsulation layer; and a second inorganic encapsulation layer (corresponding to the third inorganic layer described above) on the organic encapsulation layer.

The first inorganic encapsulation layer may extend from the display area to the non-display area, may be disposed on the first inorganic layer to cover the organic layer, and may extend to the inside of the first groove.

The second inorganic encapsulation layer may extend from the display area to the non-display area, may be disposed on the second inorganic layer, and may extend to the inside of the first groove.

The display device according to the embodiments of the present disclosure may further include a touch insulating layer extending from the display area to the non-display area, disposed on the second inorganic encapsulation layer, and overlapping the organic layer.

According to the embodiments of the present disclosure, it is possible to provide a display device which can prevent moisture penetration while enabling a narrow bezel.

According to the embodiments of the present disclosure, it is possible to provide a display device which can prevent a layer lifting phenomenon while enabling a narrow bezel.

According to the embodiments of the present disclosure, by having a narrow bezel structure, it is possible to achieve light weight of a display device.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 is a system configuration diagram of a display device according to embodiments of the present disclosure.

FIG. 2 shows a display panel according to embodiments of the present disclosure.

FIG. 3 shows a substrate of a display panel according to embodiments of the present disclosure.

FIG. 4 is a cross-sectional view of a display panel according to embodiments of the present disclosure.

FIGS. 5 and 6 are cross-sectional views of some bezel areas having a narrow bezel structure and moisture penetration preventing structure in a display panel according to embodiments of the present disclosure.

FIGS. 7 to 9 are examples of the structures of an organic layer for forming a narrow bezel structure and moisture penetration preventing structure in a display panel according to embodiments of the present disclosure.

FIGS. 10 and 11 are examples of the structures of a first groove for forming a narrow bezel structure and moisture penetration preventing structure in a display panel according to embodiments of the present disclosure.

FIG. 12 is a cross-sectional view of another bezel area having a narrow bezel structure and moisture penetration preventing structure in a display panel according to embodiments of the present disclosure.

### DETAILED DESCRIPTION

Reference will now be made in detail to embodiments of the present disclosure, examples of which may be illustrated in the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including,” and so on, used in the description and claims, should not be interpreted as being restricted to the means listed thereafter unless specifically stated otherwise. Where an indefinite or definite article is used when referring to a singular noun, e.g., “a,” “an,” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

When it is mentioned that a first element “is connected or coupled to,” “contacts or overlaps,” etc., a second element, it should be interpreted that not only can the first element “be directly connected or coupled to” or “directly contact or overlap” the second element, but a third element can also be “interposed” between the first and second elements or the first and second elements can “be connected or coupled to,” “contact or overlap,” etc., each other via a fourth element. Here, another component may be included in at least one of the at least two components which are “connected,” “coupled,” or “linked” with each other.

In descriptions for time flow relationships of components, an operating method or a fabricating method, in the case where pre and post relationships in terms of time or pre and post relationships in terms of flow are described, for example, by “after,” “following,” “next,” or “before,” non-continuous cases may be included unless “immediately” or “directly” is used.

In the case where a numerical value for a component or its corresponding information (e.g., a level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings.

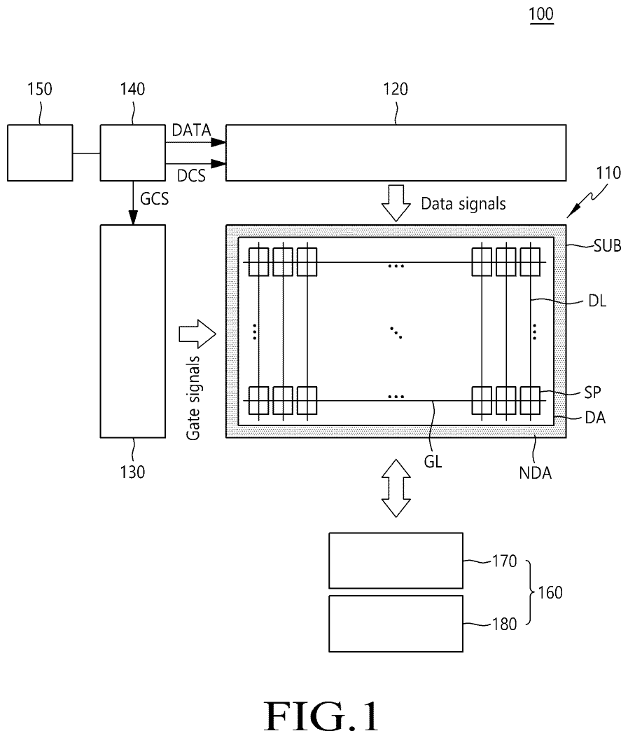

FIG. 1 is a system configuration diagram of a display device 100 according to embodiments of the present disclosure.

As shown in FIG. 1, the display device 100 according to the embodiments of the present disclosure may include a display panel 110 and a display driving circuit as components for displaying an image. The display driving circuit as a circuit for driving the display panel 110 may include a data driving circuit 120, a gate driving circuit 130 and a display controller 140.

The display panel 110 may include a substrate SUB and a plurality of subpixels SP which are disposed on the substrate SUB.

The substrate SUB of the display panel 110 may include a display area DA capable of displaying an image and a non-display area NDA located outside the display area DA.

The plurality of subpixels SP for displaying an image may be disposed in the display area DA, and the non-display area NDA may include a pad area located in a first direction from the display area DA.

In the display panel 110 according to the embodiments of the present disclosure, the non-display area NDA may be very small. In the present specification, the non-display area NDA may also be referred to as a “bezel.”

For example, the non-display area NDA may include a first non-display area which is located outside the display area DA in the first direction, a second non-display area which is located outside the display area DA in a second direction different from the first direction, a third non-display area which is located outside the display area DA in a direction opposite to the first direction, and a fourth non-display area which is located outside the display area DA in a direction opposite to the second direction. One or two among the first to fourth non-display areas may include the pad area to which the data driving circuit 120 is connected or bonded. Two or three among the first to fourth non-display areas in which the pad area is not included may be very small in size. For example, the first non-display area may include the pad area, and the sizes of the second non-display area, the third non-display area and the fourth non-display area may be very small.

For another example, the boundary area between the display area DA and the non-display area NDA may be bent, and thus, the non-display area NDA may be located under the display area DA. In this case, when a user looks at the display device 100 from the front, little or no non-display area NDA may be visible to the user. To the user, the display device 100 may appear bezel-less.

Various types of signal lines for driving the plurality of subpixels SP may be disposed on the substrate SUB of the display panel 110.

The display device 100 according to the embodiments of the present disclosure may be a liquid crystal display device or the like, or may be a self-emission display device in which the display panel 110 self-emits light. When the display device 100 according to the embodiments of the present disclosure is a self-emission display device, each of the plurality of subpixels SP may include a light emitting element.

For example, the display device 100 according to the embodiments of the present disclosure may be an organic light emitting display device in which a light emitting element is implemented using an organic light emitting diode (OLED). For another example, the display device 100 according to the embodiments of the present disclosure may be an inorganic light emitting display device in which a light emitting element is implemented using an inorganic-based light emitting diode. For still another example, the display device 100 according to the embodiments of the present disclosure may be a quantum dot display device in which a light emitting element is implemented using quantum dots as semiconductor crystals which self-emit light.

The structure of each of the plurality of subpixels SP may vary depending on the type of the display device 100. For example, when the display device 100 is a self-emission display device in which each subpixel SP self-emits light, each subpixel SP may include a self-emission light emitting element, at least one transistor and at least one capacitor.

For example, the various types of signal lines may include a plurality of data lines DL which transfer data signals (also referred to as data voltages or image signals) and a plurality of gate lines GL which transfer gate signals (also referred to as scan signals).

For example, the plurality of data lines DL and the plurality of gate lines GL may intersect each other. Each of the plurality of data lines DL may be disposed to extend in a first direction, and each of the plurality of gate lines GL may be disposed to extend in a second direction. The first direction may be a column direction, and the second direction may be a row direction. Alternatively, the first direction may be a row direction, and the second direction may be a column direction. Hereunder, for the sake of convenience in explanation, it will be described as an example that each of the plurality of data lines DL is disposed in a column direction and each of the plurality of gate lines GL is disposed in a row direction.

The data driving circuit 120 as a circuit for driving the plurality of data lines DL may output data signals to the plurality of data lines DL.

The data driving circuit 120 may receive image data DATA of a digital type from the display controller 140, may convert the received image data DATA into data signals of an analog type, and may output the data signals to the plurality of data lines DL.

For example, the data driving circuit 120 may be connected to the display panel 110 in a tape automated bonding (TAB) method, may be connected to bonding pads of the display panel 110 in a chip-on-glass (COG) or chip-on-panel (COP) method, or may be connected to the display panel 110 by being implemented in a chip-on-film (COF) method.

The data driving circuit 120 may be connected to one side (e.g., the upper side or the lower side) of the display panel 110. Unlike this, depending on a driving method, a panel design method, etc., the data driving circuit 120 may be connected to both sides (e.g., the upper side and the lower side) of the display panel 110, or may be connected to at least two sides of the four sides of the display panel 110.

The data driving circuit 120 may be connected to the outside of the display area DA of the display panel 110, but unlike this, may be disposed in the display area DA of the display panel 110.

The gate driving circuit 130 as a circuit for driving the plurality gate lines GL may output gate signals to the plurality of gate lines GL.

The gate driving circuit 130 may be supplied with a first gate voltage corresponding to a turn-on level voltage and a second gate voltage corresponding to a turn-off level voltage along with various gate driving control signals GCS, may generate gate signals, and may supply the generated gate signals to the plurality of gate lines GL.

In the display device 100 according to the embodiments of the present disclosure, the gate driving circuit 130 may be embedded in the display panel 110 in a gate-in-panel (GIP) type. When the gate driving circuit 130 is a gate-in-panel (GIP) type, the gate driving circuit 130 may be formed on the substrate SUB of the display panel 110 during the manufacturing process of the display panel 110.

In the display device 100 according to the embodiments of the present disclosure, the gate driving circuit 130 may be disposed in the display area DA of the display panel 110. For example, the gate driving circuit 130 may be disposed in a first partial area in the display area DA (e.g., a left area or a right area in the display area DA). For another example, the gate driving circuit 130 may be disposed in a first partial area in the display area DA (e.g., a left area or a right area in the display area DA) and a second partial area in the display area DA (e.g., the right area or the left area in the display area DA). For still another example, the gate driving circuit 130 may be disposed by being distributed over the entire display area DA.

In the present disclosure, the gate driving circuit 130 which is embedded in the display panel 110 in a gate-in-panel (GIP) type is referred to as a “gate-in-panel circuit.”

The display controller 140 as a device for controlling the data driving circuit 120 and the gate driving circuit 130 may control driving timing for the plurality of data lines DL and driving timing for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from a host system 150 and may supply image data DATA to the data driving circuit 120 on the basis of the input image data.

The display controller 140 may be implemented as a component separate from the data driving circuit 120 or may be implemented as an integrated circuit by being integrated with the data driving circuit 120.

The display controller 140 may be a timing controller which is used in general display technology, may be a control device which includes a timing controller and is capable of further performing other control functions, may be a control device which is different from a timing controller, or may be a circuit in a control device. The display controller 140 may be implemented by various circuits or electronic parts such as an integrated circuit (IC), a field programmable gate array (FPGA), an application specific integrated circuit (ASIC) and a processor.

The display controller 140 may be mounted on a printed circuit board, a flexible printed circuit or the like, and may be electrically connected to the data driving circuit 120 and the gate driving circuit 130 through the printed circuit board, the flexible printed circuit or the like.

The display controller 140 may transmit and receive signals to and from the data driving circuit 120 according to at least one predetermined interface. For example, the interface may include a low voltage differential signaling (LVDS) interface, an EPI (embedded clock point-point interface), a serial peripheral interface (SPI), etc.

In order to further provide a touch sensing function as well as an image display function, the display device 100 according to the embodiments of the present disclosure may include a touch sensor and a touch sensing circuit 160 which, by sensing the touch sensor, detects whether a touch event has occurred by a touch object such as a finger or a pen or detects a touch position.

The touch sensing circuit 160 may include a touch driving circuit 170, which generates and outputs touch sensing data by driving and sensing the touch sensor, and a touch controller 180 which is able to detect the occurrence of a touch event or detect a touch position using the touch sensing data.

The touch sensor may include a plurality of sensor electrodes. The touch sensor may further include a plurality of touch lines for electrically connecting the plurality of sensor electrodes and the touch driving circuit 170.

The touch sensor may exist in the form of a touch panel outside the display panel 110 or may exist inside the display panel 110. In the case where the touch sensor exists in the form of a touch panel outside the display panel 110, the touch sensor may be referred to as an external type. When the touch sensor is an external type, the touch panel and the display panel 110 may be separately manufactured and be coupled during an assembly process. The external type touch panel may include a substrate for a touch panel and a plurality of sensor electrodes on the substrate for a touch panel.

When the touch sensor exists inside the display panel 110, the touch sensor may be formed on the substrate SUB together with signal lines and electrodes related with display driving during the process of manufacturing the display panel 110.

The touch driving circuit 170 may generate touch sensing data by supplying a touch driving signal to at least one of the plurality of sensor electrodes and sensing at least one of the plurality of sensor electrodes.

The touch sensing circuit 160 may perform touch sensing in a self-capacitance sensing method or a mutual-capacitance sensing method.

In the case where the touch sensing circuit 160 performs touch sensing in the self-capacitance sensing method, the touch sensing circuit 160 may perform touch sensing on the basis of the capacitance between each sensor electrode and a touch object (e.g., a finger, a pen, etc.). According to the self-capacitance sensing method, each of the plurality of sensor electrodes may serve as both a driving sensor electrode and a sensing sensor electrode. The touch driving circuit 170 may drive all or some of the plurality of sensor electrodes, and may sense all or some of the plurality of sensor electrodes.

In the case where the touch sensing circuit 160 performs touch sensing in the mutual-capacitance sensing method, the touch sensing circuit 160 may perform touch sensing on the basis of the capacitance between sensor electrodes. According to the mutual-capacitance sensing method, the plurality of sensor electrodes are divided into driving sensor electrodes and sensing sensor electrodes. The touch driving circuit 170 may drive the driving sensor electrodes and sense the sensing sensor electrodes.

The touch driving circuit 170 and the touch controller 180 included in the touch sensing circuit 160 may be implemented as separate devices or may be implemented as a single device. Further, the touch driving circuit 170 and the data driving circuit 120 may be implemented as separate devices or may be implemented as a single device.

The display device 100 may further include a power supply circuit, etc. which supply various types of power to the display driving circuit and/or the touch sensing circuit 160.

The display device 100 according to the embodiments of the present disclosure may be a mobile terminal such as a smart phone and a tablet or a monitor or a television (TV) of various sizes. However, the display device 100 according to the embodiments of the present disclosure is not limited thereto, and may be a display of various types and various sizes capable of displaying information or an image.

The display device 100 according to the embodiments of the present disclosure may further include an electronic device such as a camera (an image sensor) and a sensor. For example, the sensor may be a sensor which detects an object or a human body by receiving light such as infrared light, ultrasonic light, and ultraviolet light.

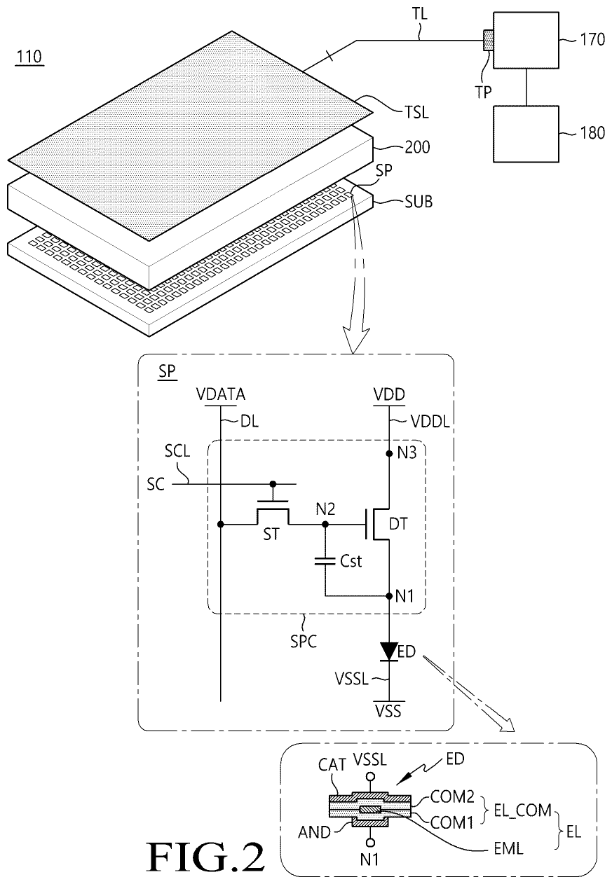

FIG. 2 shows a display panel 110 according to embodiments of the present disclosure.

As illustrated in FIG. 2, the display panel 110 may include a substrate SUB on which a plurality of subpixels SP are disposed, and an encapsulation layer 200 over the substrate SUB. The encapsulation layer 200 may also be referred to as an encapsulation substrate or an encapsulation part.

As shown in FIG. 2, in the case where the display device 100 according to the embodiments of the present disclosure is a self-emission display device, each of the plurality of subpixels SP which are disposed on the substrate SUB may include a light emitting element ED and a subpixel circuit SPC for driving the light emitting element ED.

As illustrated in FIG. 2, the subpixel circuit SPC may include a plurality of pixel driving transistors and at least one capacitor for driving the light emitting element ED. In the present disclosure, the subpixel circuit SPC may drive the light emitting element ED by supplying driving current to the light emitting element ED at predetermined timing. The light emitting element ED may be driven by the driving current to emit light.

The plurality of pixel driving transistors may include a driving transistor DT for driving the light emitting element ED and a scan transistor ST which is turned on or off according to a scan signal SC.

The driving transistor DT may supply driving current to the light emitting element ED.

The scan transistor ST may be configured to control the electrical state of a corresponding node in the subpixel circuit SPC or control the state or operation of the driving transistor DT.

The at least one capacitor may include a storage capacitor Cst for maintaining a constant voltage during a frame.

In order to drive the subpixel SP, a data signal VDATA as an image signal, the scan signal SC as a gate signal, etc. may be applied to the subpixel SP. Further, in order to drive the subpixel SP, a common pixel driving voltage including a first common driving voltage VDD and a second common driving voltage VSS may be applied to the subpixel SP.

The light emitting element ED may include an anode AND, an intermediate layer EL and a cathode CAT. The intermediate layer EL may be disposed between the anode AND and the cathode CAT.

In the case where the light emitting element ED is an organic light emitting element, the intermediate layer EL may include a light emitting layer EML, a first common intermediate layer COM1 between the anode AND and the light emitting layer EML, and a second common intermediate layer COM2 between the light emitting layer EML and the cathode CAT. The first common intermediate layer COM1 and the second common intermediate layer COM2 may be collectively referred to as a common intermediate layer EL_COM.

The light emitting layer EML may be disposed in each subpixel SP, and the common intermediate layer EL_COM may be disposed in common in a plurality of subpixels SP.

The light emitting layer EML may be disposed in each light emitting area, and the common intermediate layer EL_COM may be disposed in common in a plurality of light emitting areas and non-light emitting areas.

For example, the first common intermediate layer COM1 of the common intermediate layer EL_COM may include a hole injection layer (HIL) and a hole transfer layer (HTL). The second common intermediate layer COM2 of the common intermediate layer EL_COM may include an electron transfer layer (ETL) and an electron injection layer (EIL).

The hole injection layer may inject holes from the anode AND to the hole transfer layer, the hole transfer layer may transfer holes to the light emitting layer EML, the electron injection layer may inject electrons from the cathode ACT to the electron transfer layer, and the electron transfer layer may transfer electrons to the light emitting layer EML.

For example, the cathode CAT may be electrically connected to a second common driving voltage line VSSL. The second common driving voltage VSS, which is a type of common pixel driving voltage, may be applied to the cathode CAT through the second common driving voltage line VSSL. The anode AND may be electrically connected directly or indirectly (through another transistor) to a first node N1 of the driving transistor DT of each subpixel SP. In the present disclosure, the second common driving voltage VSS may also be referred to as a “base voltage,” and the second common driving voltage line VSSL may also be referred to as a “base voltage line.”

For example, the anode AND may be a pixel electrode which is disposed in each subpixel SP, and the cathode CAT may be a common electrode which is disposed in common in a plurality of subpixels SP. For another example, the cathode CAT may be a pixel electrode which is disposed in each subpixel SP, and the anode AND may be a common electrode which is disposed in common in a plurality of subpixels SP. Hereinbelow, for the sake of convenience in explanation, it is assumed that the anode AND is a pixel electrode and the cathode CAT is a common electrode.

Each light emitting element ED may be configured with the overlapping portions of the anode AND, the light emitting layer EML in the intermediate layer EL and the cathode CAT. A predetermined light emitting area may be formed by each light emitting element ED. For example, the light emitting area of each light emitting element ED may include the overlapping portions of the anode AND, the light emitting layer EML in the intermediate layer EL and the cathode CAT.

For example, the light emitting element ED may be an organic light emitting diode (OLED), an inorganic-based light emitting diode (LED) or a quantum dot light emitting element. For example, when the light emitting element ED is an organic light emitting diode (OLED), the intermediate layer EL in the light emitting element ED may include an intermediate layer EL which includes an organic material.

The driving transistor DT may be a driving transistor for supplying driving current to the light emitting element ED. The driving transistor DT may be connected between a first common driving voltage line VDDL and the light emitting element ED.

The driving transistor DT may have a first node N1, a second node N2 and a third node N3. The first node N1 may be electrically connected to the light emitting element ED, the second node N2 may be applied with the data signal VDATA, and the third node N3 may be applied with the first common driving voltage VDD from the first common driving voltage line VDDL.

In the driving transistor DT, the second node N2 may be a gate node, the first node N1 may be a source node or a drain node, and the third node N3 may be a drain node or a source node. Hereinbelow, for the sake of convenience in explanation, it will be described as an example that, in the driving transistor DT, the second node N2 is a gate node, the first node N1 is a source node and the third node N3 is a drain node.

The scan transistor ST included in the subpixel circuit SPC illustrated in FIG. 2 may be a switching transistor for transferring the data signal VDATA as an image signal to the second node N2 which is the gate node of the driving transistor DT.

The scan transistor ST may be on-off controlled by the scan signal SC as a gate signal applied through a scan line SCL which is a type of gate line GL, and thus, may control the electrical connection between the second node N2 of the driving transistor DT and a data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode which is electrically connected to the first node N1 of the driving transistor DT or corresponds to the first node N1 of the driving transistor DT, and a second capacitor electrode which is electrically connected to the second node N2 of the driving transistor DT or corresponds to the second node N2 of the driving transistor DT.

The storage capacitor Cst may be not a parasitic capacitor (e.g., Cgs or Cgd) which is an internal capacitor likely to exist between the first node N1 and the second node N2 of the driving transistor DT but an external capacitor which is intentionally designed outside the driving transistor DT.

Each of the driving transistor DT and the scan transistor ST may be an n-type transistor or a p-type transistor.

The display panel 110 may have a top emission structure or a bottom emission structure.

When the display panel 110 has the top emission structure, at least a portion of the subpixel circuit SPC may overlap at least a portion of the light emitting element ED in the vertical direction. Accordingly, the area of a light emitting area may increase, and an aperture ratio may increase.

When the display panel 110 has the bottom emission structure, the subpixel circuit SPC may not overlap the light emitting element ED in the vertical direction.

As illustrated in FIG. 2, the subpixel circuit SPC may have a 2T(transistor)1C(capacitor) structure including two transistors DT and ST and one capacitor Cst. As the case may be, the subpixel circuit SPC may further include at least one transistor and may further include at least one capacitor.

For example, the subpixel circuit SPC may have an 8T1C structure including eight transistors and one capacitor. For another example, the subpixel circuit SPC may have a 6T2C structure including six transistors and two capacitors. For still another example, the subpixel circuit SPC may have a 7T1C structure including seven transistors and one capacitor.

The types and number of gate signals supplied to the subpixel SP and the types and number of gate lines may vary depending on the structure of the subpixel circuit SPC. Further, the types and number of common pixel driving voltages supplied to the subpixel SP may vary depending on the structure of the subpixel circuit SPC.

Because circuit elements (in particular, the light emitting element ED implemented by an organic light emitting diode (OLED) including an organic material) in each subpixel SP are vulnerable to external moisture or oxygen, the encapsulation layer 200 for preventing external moisture or oxygen from penetrating into the circuit elements (in particular, the light emitting element ED) may be disposed. The encapsulation layer 200 may be configured in various shapes to prevent light emitting elements ED from contacting moisture or oxygen.

With reference to FIG. 2, in order to sense a user's touch, the display device 100 according to the embodiments of the present disclosure may include a touch sensor layer TSL which includes a plurality of sensor electrodes, a touch driving circuit 170 which is configured to sense the plurality of sensor electrodes, and a touch controller 180 which is configured to determine whether a touch event has occurred and touch coordinates using a sensing result (touch sensing data) of the touch driving circuit 170.

The touch sensor layer TSL may be embedded in the display panel 110. For example, the touch sensor layer TSL may be disposed on the encapsulation layer 200 in the display panel 110.

The display panel 110 may further include a plurality of touch pads TP to which the touch driving circuit 170 is electrically connected, and a plurality of touch routing interconnections TL for electrically connecting the plurality of sensor electrodes included in the touch sensor layer TSL to the plurality of touch pads TP to which the touch driving circuit 170 is connected.

Meanwhile, the display device 100 according to the embodiment of the present disclosure may have an extremely narrow bezel structure in which the non-display area NDA of the display panel 110 is very small or is almost absent.

Hereinafter, the extremely narrow bezel structure of the display panel 110 of the display device 100 according to the embodiment of the present disclosure will be described.

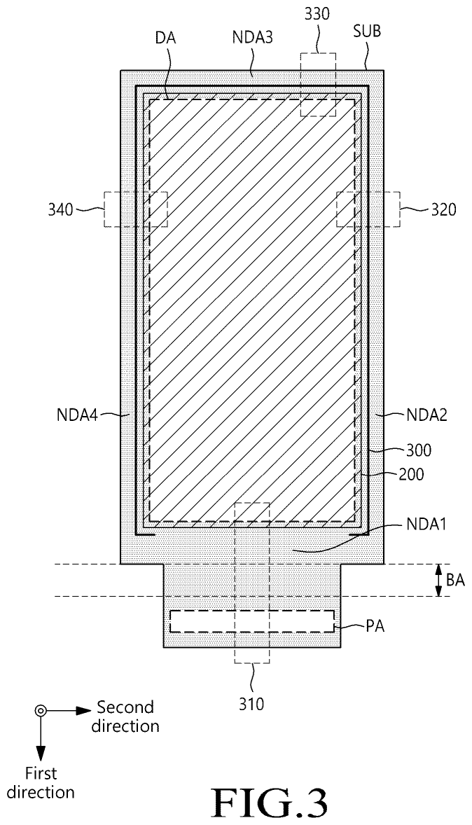

FIG. 3 shows a substrate SUB of a display panel 110 according to embodiments of the present disclosure.

As shown in FIG. 3, the substrate SUB of the display panel 110 according to the embodiments of the present disclosure may include a display area DA where an image may be displayed and a non-display area NDA where an image is not displayed.

As shown in FIG. 3, the non-display area NDA may include a first non-display area NDA1 which is located in a first direction from the display area DA, a second non-display area NDA2 which is located in a second direction from the display area DA, a third non-display area NDA3 which is located in a direction opposite to the first direction from the display area DA, and a fourth non-display area NDA4 which is located in a direction opposite to the second direction from the display area DA. For example, the first direction may be a column direction (the Y-axis direction), and the second direction intersecting the first direction may be a row direction (the X-axis direction).

As shown in FIG. 3, the first non-display area NDA1 may include a pad area PA in which a plurality of pads are disposed.

In the pad area PA, the plurality of pads to which driving circuits are electrically connected may be disposed. A plurality of driving circuits or a printed circuit board may be electrically connected. For example, the plurality of pads may include a plurality of display pads and a plurality of touch pads. A plurality of data lines DL, a first common driving voltage line VDDL and a second common driving voltage line VSSL may be electrically connected to the plurality of display pads. A plurality of touch routing interconnections TL may be electrically connected to the plurality of touch pads.

As illustrated in FIG. 3, the first non-display area NDA1 may further include a bending area BA. In this case, the substrate SUB may be a flexible substrate. As the case may be, the first non-display area NDA1 may not include the bending area BA.

As shown in FIG. 3, the display panel 110 may further include a ground interconnection which is disposed in the non-display area NDA of the substrate SUB. The ground interconnection may be disposed from one point of the pad area PA to another point of the pad area PA via the second non-display area NDA2, the third non-display area NDA3 and the fourth non-display area NDA4.

As illustrated in FIG. 3, in the display panel 110 according to the embodiments of the present disclosure, an encapsulation layer 200 may have a structure in which an inorganic layer and an organic layer are stacked. In this case, the edge of the encapsulation layer 200 may be the edge of the organic layer.

As shown in FIG. 3, the substrate SUB of the display panel 110 according to the embodiments of the present disclosure may have a first groove 300 which is located outside the display area DA. That is to say, the first groove 300 which is formed in the substrate SUB may be located in the non-display area NDA.

As illustrated in FIG. 3, the first groove 300 may be formed in the substrate SUB in the form of a trench along the second non-display area NDA2, the third non-display area NDA3 and the fourth non-display area NDA4.

As shown in FIG. 3, in at least a partial area in the first non-display area NDA1, the first groove 300 may not be formed in the substrate SUB. The at least a partial area in the first non-display area NDA1 in which the first groove 300 is not formed in the substrate SUB may be an area between the display area DA and the pad area PA.

As illustrated in FIG. 3, the first groove 300 formed in the substrate SUB may have a U-shape.

As illustrated in FIG. 3, the display panel 110 may include a first area 310, a second area 320, a third area 330 and a fourth area 340. In the display panel 110, the first area 310 may include the display area DA and the first non-display area NDA1, the second area 320 may include the display area DA and the second non-display area NDA2, the third area 330 may include the display area DA and the third non-display area NDA3, and the fourth area 340 may include the display area DA and the fourth non-display area NDA4.

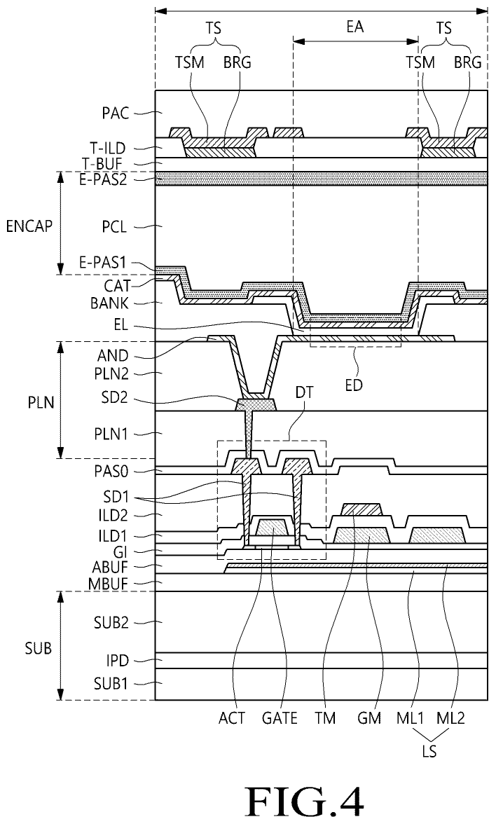

FIG. 4 is a cross-sectional view of a display panel 110 according to embodiments of the present disclosure.

As illustrated in FIG. 4, a substrate SUB may include a first substrate SUB1, an intermediate insulating layer IPD and a second substrate SUB2. The intermediate insulating layer IPD may be located between the first substrate SUB1 and the second substrate SUB2. By configuring the substrate SUB with the first substrate SUB1, the intermediate insulating layer IPD and the second substrate SUB2, it is possible to prevent moisture penetration. For example, the first substrate SUB1 and the second substrate SUB2 may be an polyimide (PI) substrates. In the substrate SUB, the first substrate SUB1 may be referred to as a primary PI substrate, and the second substrate SUB2 may be referred to as a secondary PI substrate.

As illustrated in FIG. 4, on the substrate SUB, various patterns ACT, SD1 and GATE for forming a transistor such as a driving transistor DT, various insulating layers MBUF, ABUF1, ABUF2, GI, ILD1, ILD2 and PAS0), and various metal patterns TM, GM, ML1 and ML2 may be disposed.

As illustrated in FIG. 4, a multi-buffer layer MBUF may be disposed on the second substrate SUB2, and an active buffer layer ABUF may be disposed on the multi-buffer layer MBUF.

A first metal layer ML1 and a second metal layer ML2 may be disposed on the multi-buffer layer MBUF. The first metal layer ML1 and the second metal layer ML2 may be a shield pattern LS which shields light.

The active buffer layer ABUF may be disposed on the first metal layer ML1 and the second metal layer ML2. An active layer ACT of the driving transistor DT may be disposed on the active buffer layer ABUF.

A gate insulating layer GI may be disposed to cover the active layer ACT.

A gate electrode GATE of the driving transistor DT may be disposed on the gate insulating layer GI. At a location different from a location where the driving transistor DT is formed, a gate material layer GM may be disposed on the gate insulating layer GI together with the gate electrode GATE of the driving transistor DT.

A first interlayer insulating layer ILD1 may be disposed to cover the gate electrode GATE and the gate material layer GM. A metal pattern TM may be disposed on the first interlayer insulating layer ILD1. The metal pattern TM may be located at a location different from the location where the driving transistor DT is formed. A second interlayer insulating layer ILD2 may be disposed to cover the metal pattern TM on the first interlayer insulating layer ILD1.

Two first source-drain electrode patterns SD1 may be disposed on the second interlayer insulating layer ILD2. One of the two first source-drain electrode patterns SD1 is the source node of the driving transistor DT, and the other may be the drain node of the driving transistor DT.

The two first source-drain electrode patterns SD1 may be electrically connected to one side and the other side of the active layer ACT through contact holes of the second interlayer insulating layer ILD2, the first interlayer insulating layer ILD1 and the first gate insulating layer GI.

A portion of the active layer ACT which overlaps the first gate electrode GATE is a channel area. One of the two first source-drain electrode patterns SD1 may be connected to one side of the channel area in the active layer ACT, and the other of the two first source-drain electrode patterns SD1 may be connected to the other side of the channel area in the active layer ACT.

A passivation layer PAS0 is disposed to cover the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one (corresponding to the second node N2 of the driving transistor DT in the subpixel SP of FIG. 2) of the two first source-drain electrode patterns SD1, through a contact hole of the first planarization layer PLN1.

The second planarization layer PLN2 may be disposed to cover the second source-drain electrode pattern SD2. A light emitting element ED may be disposed on the second planarization layer PLN2.

Observing the stack structure of the light emitting element ED, an anode AND may be disposed on the second planarization layer PLN2. The anode AND may be electrically connected to the second source-drain electrode pattern SD2 through a contact hole of the second planarization layer PLN2.

A bank BANK may be disposed to cover a portion of the anode AND. A portion of the bank BANK corresponding to a light emitting area EA of the subpixel SP may be open.

A portion of the anode AND may be exposed through the opening (the open portion) of the bank BANK. A light emitting layer EL may be located on the side portion of the bank BANK and in the opening (the open portion) of the bank BANK. The entirety or a part of the light emitting layer EL may be located between adjacent portions of the bank BANK.

In the opening of the bank BANK, the light emitting layer EL may contact the anode AND. A cathode CAT may be disposed on the light emitting layer EL.

The light emitting element ED may be formed by the anode AND, the light emitting layer EL and the cathode CAT. The light emitting layer EL may include an organic layer.

An encapsulation layer ENCAP may be disposed on the light emitting element ED described above.

The encapsulation layer ENCAP may have a single-layer structure or a multilayer structure. For example, as illustrated in FIG. 4, the encapsulation layer ENCAP may include a first encapsulation layer E-PAS1, a second encapsulation layer PCL and a third encapsulation layer E-PAS2.

For example, the first encapsulation layer E-PAS1 and the third encapsulation layer E-PAS2 may be referred to as a first inorganic encapsulation layer and a second inorganic encapsulation layer, respectively, and the second encapsulation layer PCL may be referred to as an organic encapsulation layer. For example, the first encapsulation layer E-PAS1 and the third encapsulation layer E-PAS2 may be inorganic layers. For example, the second encapsulation layer PCL may be an organic layer. Among the first encapsulation layer E-PAS1, the second encapsulation layer PCL and the third encapsulation layer E-PAS2, the second encapsulation layer PCL may be the thickest and serve as a planarization layer.

The first encapsulation layer E-PAS1 may be disposed on the cathode CAT, and may be disposed closest to the light emitting element ED. The first encapsulation layer E-PAS1 may be formed of an inorganic insulating material capable of being deposited at low temperature. For example, the first encapsulation layer E-PAS1 may include silicon nitride (SiNx), silicon oxide (SiOx), silicon oxynitride (SiON) or aluminum oxide (Al2O3). Since the first encapsulation layer E-PAS1 is deposited in a low temperature atmosphere, during a deposition process, the first encapsulation layer E-PAS1 may prevent the light emitting layer EL including an organic material vulnerable to a high temperature atmosphere from being damaged.

The second encapsulation layer PCL may be formed to have a smaller area than the first encapsulation layer E-PAS1. In this case, the second encapsulation layer PCL may be formed to expose both ends of the first encapsulation layer E-PAS1. The second encapsulation layer PCL may serve to perform a buffering function of relieving the stress between layers due to warpage of the display device 100, and may also serve to enhance planarization performance. For example, the second encapsulation layer PCL may include acrylic resin, epoxy resin, polyimide, polyethylene or silicon oxycarbon (SiOC), and may be formed of an organic insulating material. For example, the second encapsulation layer PCL may be formed using an inkjet method.

The third encapsulation layer E-PAS2 may be formed over the substrate SUB formed with the second encapsulation layer PCL to cover the upper surface and the side surface of each of the second encapsulation layer PCL and the first encapsulation layer E-PAS1. The third encapsulation layer E-PAS2 may minimize or prevent external moisture or oxygen from penetrating into the first inorganic encapsulation layer E-PAS1 and the organic encapsulation layer PCL. For example, the third encapsulation layer E-PAS2 is formed of an inorganic insulating material such as silicon nitride (SiNx), silicon oxide (SiOx), silicon oxynitride (SiON) and aluminum oxide (Al2O3).

With reference to FIG. 4, when a touch sensor TS is a type in which the touch sensor TS is embedded in the display panel 110, the touch sensor TS may be disposed on the encapsulation layer ENCAP. The structure of the touch sensor TS will be described below in detail.

A touch buffer layer T-BUF may be disposed on the encapsulation layer ENCAP. The touch sensor TS may be disposed on the touch buffer layer T-BUF.

The touch sensor TS may include touch sensor metals TSM and a touch bridge metal BRG which are located at different layers.

A touch interlayer insulating layer T-ILD may be disposed between the touch sensor metals TSM and the touch bridge metal BRG.

For example, the touch sensor metals TSM may include a first touch sensor metal TSM, a second touch sensor metal TSM and a third touch sensor metal TSM which are disposed adjacent to each another. The third touch sensor metal TSM may be disposed between the first touch sensor metal TSM and the second touch sensor metal TSM, and when the first touch sensor metal TSM and the second touch sensor metal TSM are required to be electrically connected to each other, the first touch sensor metal TSM and the second touch sensor metal TSM may be electrically connected to each other through the touch bridge metal BRG which is disposed at a different layer. The touch bridge metal BRG may be electrically insulated from the third touch sensor metal TSM by the touch interlayer insulating layer T-ILD.

When the touch sensor TS is formed on the display panel 110, moisture may be generated or introduced from a chemical solution (a developer, an etchant, etc.) used in a process or from the outside. Since the touch sensor TS is disposed on the touch buffer layer T-BUF, it is possible to prevent a chemical solution or moisture from penetrating into the light emitting layer EL including an organic material during the manufacturing process of the touch sensor TS. Accordingly, the touch buffer layer T-BUF may prevent damage to the light emitting layer EL which is vulnerable to a chemical solution or moisture.

In order to prevent damage to the light emitting layer EL including an organic material, which is vulnerable to high temperature, the touch buffer layer T-BUF may be formed at a low temperature equal to or lower than a predetermined temperature (e.g., 100° C.), and is formed of an organic insulating material which has a low dielectric constant of 1 to 3. For example, the touch buffer layer T-BUF may be formed of an acrylic-based, epoxy-based or siloxan-based material. As the display device 100 warps, the encapsulation layer ENCAP may be damaged, and the touch sensor metal TSM which is located over the touch buffer layer T-BUF may break. Even when the display device 100 warps, the touch buffer layer T-BUF which is made of an organic insulating material and has planarization performance may prevent damage to the encapsulation layer ENCAP and/or the breaking phenomenon of the metals TSM and BRG configuring the touch sensor TS.

The touch buffer layer T-BUF and the touch interlayer insulating layer T-ILD may be touch insulating layers.

A protective layer PAC may be disposed to cover the touch sensor TS. The protective layer PAC may be an organic insulating layer.

Meanwhile, in a trimming margin area in the display panel 110 for an error during a trimming process, by removing various inorganic layers for forming a transistor and the inorganic layers E-PAS1 and E-PAS2 included in the encapsulation layer ENCAP, various inorganic layer cracks caused by defects that occur during trimming may be prevented from propagating into the display area DA. If a crack propagates into the display area DA, moisture may penetrate into a crack area and cause a panel defect.

In the display panel 110 which is recently mounted in a mobile terminal, the size of a bezel is gradually reduced. If a trimming margin is applied in this situation, a layer lifting phenomenon may occur due to a decrease in adhesion force between the inorganic layers E-PAS1 and E-PAS2 of the encapsulation layer ENCAP and an underlying organic layer (e.g., the planarization layers PLN), and as a result, a moisture penetration defect may occur.

Although the inorganic layers E-PAS1 and E-PAS2 of the encapsulation layer ENCAP may be located in the trimming margin area, restrictions exist in processing capabilities and there is still a risk of a crack to occur during trimming.

In consideration of these facts, the display device 100 according to the embodiments of the present disclosure may have a structure which may reduce a moisture penetration defect while enabling a narrow bezel. Such a structure is referred to as “a narrow bezel structure and moisture penetration preventing structure.”

Hereinafter, the “narrow bezel structure and moisture penetration preventing structure” of the display device 100 according to the embodiments of the present disclosure will be described.

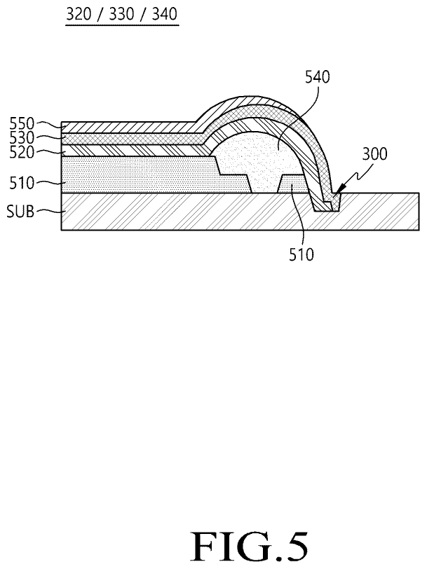

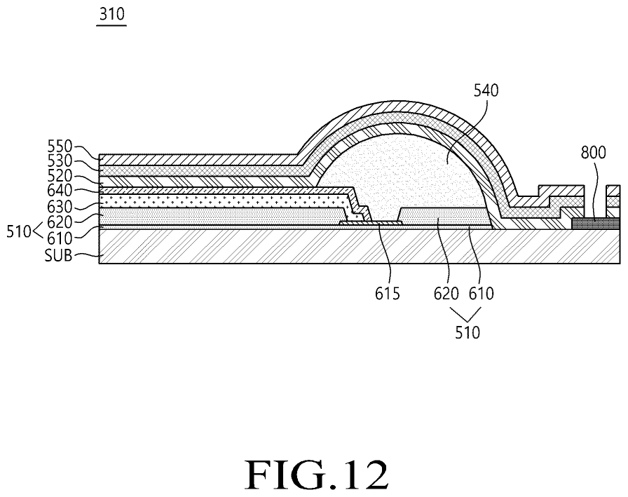

Hereinafter, the narrow bezel structure and moisture penetration preventing structure in the second to fourth non-display areas NDA2, NDA3 and NDA4) will be described with reference to FIGS. 5 to 11, and the narrow bezel structure and moisture penetration preventing structure in the first non-display area NDA1 will be described with reference to FIG. 12.

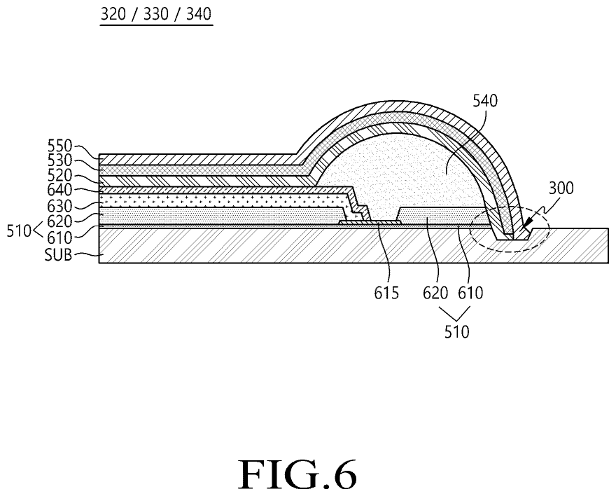

FIGS. 5 and 6 are cross-sectional views of some bezel areas (e.g., second to fourth non-display areas NDA2, NDA3 and NDA4) having a narrow bezel structure and moisture penetration preventing structure in a display panel 110 according to embodiments of the present disclosure.

With reference to FIG. 5, in order to have the narrow bezel structure and moisture penetration preventing structure, the display panel 110 according to the embodiments of the present disclosure may include a substrate SUB, a first inorganic layer 510, a second inorganic layer 520, a third inorganic layer 530 and an organic layer 540.

The substrate SUB may include a display area DA in which a plurality of subpixels SP are disposed and a non-display area NDA which is located outside the display area DA and includes a pad area PA. The substrate SUB may have a first groove 300 in the non-display area NDA.

The first inorganic layer 510 may be disposed on the substrate SUB, may extend from the display area DA to the non-display area NDA, and may have, in the non-display area NDA, a second groove which is located closer to the display area DA than the first groove 300.

An area where the first inorganic layer 510 is cut may correspond to the second groove of the first inorganic layer 510.

As the second groove is formed, the display device 100 may minimize a shock propagated along the first inorganic layer 510. For example, by including the area where the first inorganic layer 510 is cut, the display device 100 may prevent a crack from propagating along the first inorganic layer 510.

The organic layer 540 may be disposed on a portion of the first inorganic layer 510 in the non-display area NDA, and may fill the second groove of the first inorganic layer 510.

The second inorganic layer 520 may extend from the display area DA to the non-display area NDA, may be disposed on the first inorganic layer 510 to cover the organic layer 540, and may extend up to the inside of the first groove 300.

The inner surface (the rear surface) of the second inorganic layer 520 may directly contact the organic layer 540. Accordingly, a layer lifting phenomenon between the second inorganic layer 520 and the organic layer 540 may be prevented.

The third inorganic layer 530 may extend from the display area DA to the non-display area NDA, may be disposed on the second inorganic layer 520, and may extend up to the inside of the first groove 300.

With reference to FIG. 5, in order to have the narrow bezel structure and moisture penetration preventing structure, the display panel 110 according to the embodiments of the present disclosure may further include a touch insulating layer 550 which extends from the display area DA to the non-display area NDA, is disposed on the third inorganic layer 530 and overlaps the organic layer 540.

The first inorganic layer 510 may include at least one inorganic layer for forming a transistor (e.g., a driving transistor DT). For example, as illustrated in FIG. 4, the first inorganic layer 510 may include at least one inorganic layer among the multi-buffer layer MBUF, the active buffer layer ABUF, the gate insulating layer GI, the first interlayer insulating layer ILD1 and the second interlayer insulating layer ILD2.

In the display area DA, the light emitting element ED may be disposed between the first inorganic layer 510 and the second inorganic layer 520, and the encapsulation layer ENCAP may be disposed on the light emitting element ED. The second inorganic layer 520 and the third inorganic layer 530 may be included in the encapsulation layer ENCAP.

For example, as illustrated in FIG. 4, the second inorganic layer 520 may be the first encapsulation layer E-PAS1 which is included in the encapsulation layer ENCAP, and the third inorganic layer 530 may be the third encapsulation layer E-PAS2 which is included in the encapsulation layer ENCAP. The first encapsulation layer E-PAS1 may be referred to as a first inorganic encapsulation layer, and the third encapsulation layer E-PAS2 may be referred to as a second inorganic encapsulation layer.

As described above with reference to FIG. 4, the touch bridge metal BRG may be disposed on the encapsulation layer ENCAP, the touch sensor metal TSM may be disposed on the touch bridge metal BRG, and the touch interlayer insulating layer T-ILD may be disposed between the touch bridge metal BRG and the touch sensor metal TSM. The touch interlayer insulating layer T-ILD may be an inorganic layer or an organic layer.

As illustrated in FIG. 5, the touch insulating layer 550 may include the touch interlayer insulating layer T-ILD which is disposed between the touch bridge metal BRG and the touch sensor metal TSM.

As described above with reference to FIG. 4, the touch buffer layer T-BUF may be disposed between the encapsulation layer ENCAP and the touch bridge metal BRG. The touch buffer layer T-BUF may be an inorganic layer or an organic layer. In this case, the touch insulating layer 550 may include the touch buffer layer T-BUF.

As shown in FIG. 5, the touch insulating layer 550 may not extend up to the inside of the first groove 300. Unlike this, the touch insulating layer 550 may extend up to the inside of the first groove 300.

With reference to FIG. 6, when the second inorganic layer 520, the third inorganic layer 530 and the touch insulating layer 550 are disposed to extend up to the inside of the first groove 300 of the substrate SUB, the first groove 300 of the substrate SUB may have a depth or size corresponding to the total thickness of the second inorganic layer 520, the third inorganic layer 530 and the touch insulating layer 550.

For example, the first groove 300 of the substrate SUB may have a trapezoidal shape whose width increases toward the top of the substrate SUB. Due to such a shape, an area over which the second inorganic layer 520, the third inorganic layer 530 and the touch insulating layer 550 contact the substrate SUB may be significantly increased.

For example, as the area over which the second inorganic layer 520, the third inorganic layer 530 and the touch insulating layer 550 contact the substrate SUB is increased, it is possible to prevent or minimize the second inorganic layer 520, the third inorganic layer 530 and the touch insulating layer 550 from peeling off or being released from the substrate SUB.

As illustrated in FIG. 6, the first inorganic layer 510 may include a first insulating layer 610 on the substrate SUB and a second insulating layer 620 on the first insulating layer 610. The second groove of the first inorganic layer 510 may correspond to a hole or groove which is formed in the second insulating layer 620.

An area where the second insulating layer 620 of the first inorganic layer 510 is cut may correspond to the second groove of the first inorganic layer 510.

As illustrated in FIG. 6, the first inorganic layer 510 may contact the second inorganic layer 520. For example, the first insulating layer 610 may contact the second inorganic layer 520. For example, the second insulating layer 620 may contact the second inorganic layer 520. More specifically, at least one of the side surface and the upper surface of the second insulating layer 620 may contact the rear surface of the second inorganic layer 520. As the first inorganic layer 510 and the second inorganic layer 520 contact each other, it is possible to prevent the second inorganic layer 520 from peeling off or being released from the substrate SUB. For example, as the second inorganic layer 520 contacts a portion of the first inorganic layer 510, it is possible to increase the adhesion force between the second inorganic layer 520 and the substrate SUB.

According to the above description, since the bonding force between the substrate SUB and the various insulating layers 510, 520, 530, 540 and 550 included in the display panel 110 is increased, the overall reliability of the display panel 110 may be greatly improved.

As illustrated in FIG. 6, the display panel 110 according to the embodiments of the present disclosure may further include a blocking metal 615 which is disposed on the first insulating layer 610.

As illustrated in FIG. 6, both ends of the blocking metal 615 may be located between the first insulating layer 610 and the second insulating layer 620, and the portion between both ends of the blocking metal 615 may overlap the second groove of the first inorganic layer 510. In other words, a portion of the blocking metal 615 (the portion between both ends of the blocking metal 615) may be exposed through the second groove of the first inorganic layer 510.

As illustrated in FIG. 6, the blocking metal 615 may be disposed at the same layer as the shield metal LS which is disposed under a transistor (e.g., the driving transistor DT). Namely, the blocking metal 615 may include the same material as the shield metal LS.

As illustrated in FIG. 6, the blocking metal 615 may prevent the substrate SUB from being etched when the first inorganic layer 510 is etched. Through this, the blocking metal 615 may prevent moisture from penetrating downward (downward moisture penetration).

With reference to FIG. 6, the display panel 110 according to the embodiments of the present disclosure may further include at least one metal layer which is disposed between the first inorganic layer 510 and the second inorganic layer 520 and extends from the display area DA to the non-display area NDA.

As illustrated in FIG. 6, the at least one metal layer may extend up to the inside of the second groove of the first inorganic layer 510.

For example, with reference to FIG. 4, the at least one metal layer may include a first source-drain electrode layer 630 in which the first source-drain electrode pattern SD1 is formed, and a second source-drain electrode layer 640 in which the second source-drain electrode pattern SD2 is formed.

As illustrated in FIG. 6, the touch insulating layer 550 may extend up to the inside of the first groove 300.

With reference to FIGS. 5 and 6, the display panel 110 according to the embodiments of the present disclosure does not have, in the non-display area NDA, a dam structure for preventing the second encapsulation layer PCL as an organic encapsulation layer included in the encapsulation layer ENCAP from overflowing. Because of this fact, the size of the non-display area NDA may be reduced by an area where the dam structure is formed, making it easier to implement a narrow bezel.

In this way, even though the display panel 110 does not have a dam structure, due to the structure in which the second inorganic layer 520 and the third inorganic layer 530 included in the encapsulation layer ENCAP are disposed to extend up to the inside of the first groove 300 of the substrate SUB, the third inorganic layer 530 may serve as a dam which prevents the second encapsulation layer PCL, as an organic encapsulation layer included in the encapsulation layer ENCAP, from overflowing.

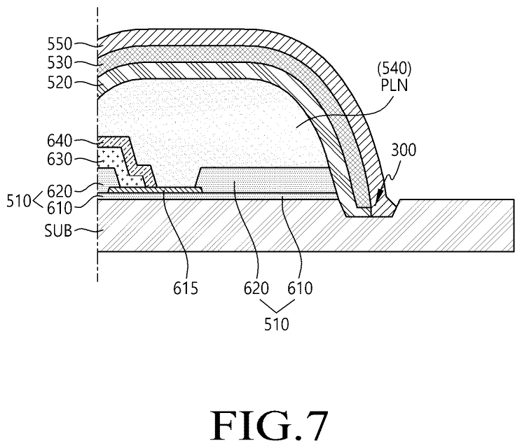

FIGS. 7 to 9 are examples of the structures of an organic layer 540 for forming a narrow bezel structure and moisture penetration preventing structure in a display panel 110 according to embodiments of the present disclosure.

As described above with reference to FIG. 4, the display panel 110 according to the embodiments of the present disclosure may include the planarization layer PLN which is disposed between the first inorganic layer 510 for forming a transistor and the second inorganic layer 520 included in the encapsulation layer ENCAP, the light emitting element ED which is disposed on the planarization layer PLN, and the bank BANK which is disposed on the planarization layer PLN and defines the light emitting area of the light emitting element ED.

As illustrated in FIG. 7, the organic layer 540 may include the planarization layer PLN, and the planarization layer PLN may be disposed on a portion of the first inorganic layer 510 in the non-display area NDA and may fill the second groove of the first inorganic layer 510. For example, the planarization layer PLN included in the organic layer 540 may be the second planarization layer PLN2 which is located immediately under the anode AND.

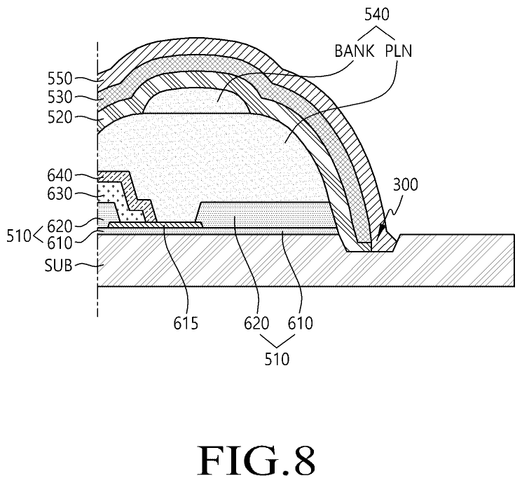

As illustrated in FIG. 8, the organic layer 540 may further include the bank BANK on the planarization layer PLN.

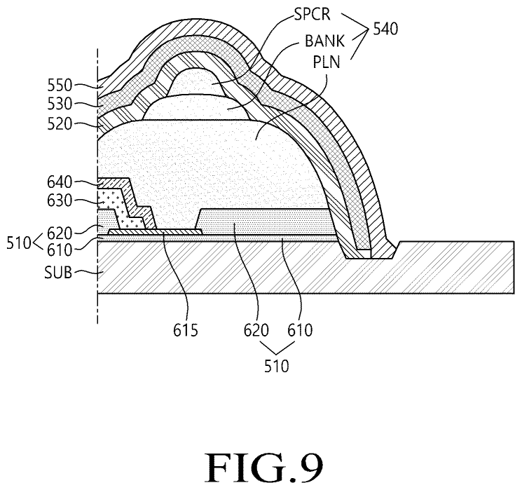

As illustrated in FIG. 9, in addition to the planarization layer PLN and the bank BANK, the organic layer 540 may further include a spacer SPCR on the bank BANK.

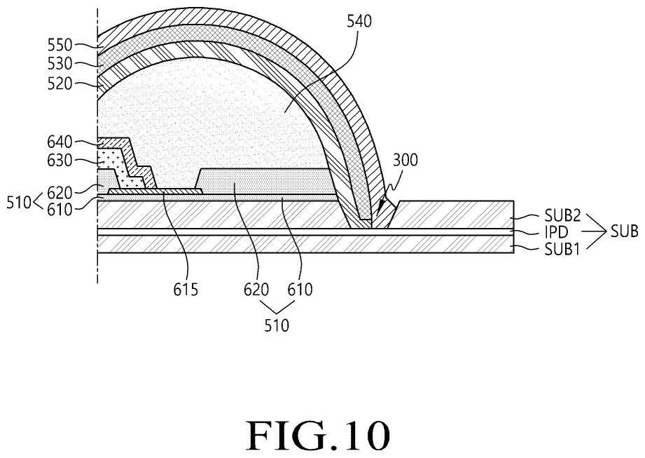

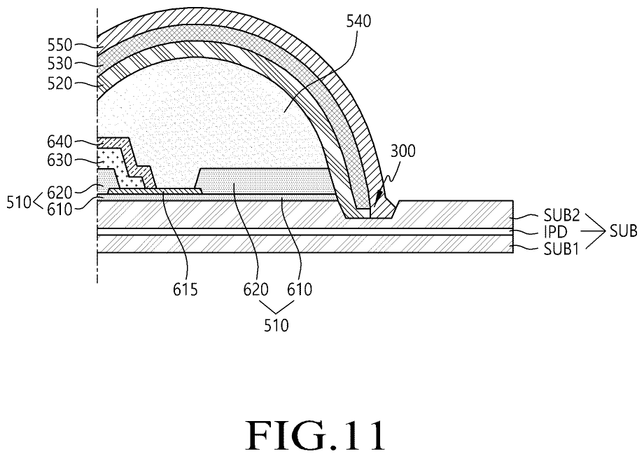

FIGS. 10 and 11 are examples of the structures of a first groove 300 for forming a narrow bezel structure and moisture penetration preventing structure in a display panel 110 according to embodiments of the present disclosure.

With reference to FIGS. 10 and 11, in the display panel 110 according to the embodiments of the present disclosure, the substrate SUB may include a first substrate SUB1, an intermediate insulating layer IPD on the first substrate SUB1, and a second substrate SUB2 on the intermediate insulating layer IPD.

As illustrated in FIGS. 10 and 11, the first groove 300 of the substrate SUB may be formed in the second substrate SUB2.

As illustrated in FIG. 10, the first groove 300 of the substrate SUB may be formed to completely pass through the second substrate SUB2.

Unlike this, as shown in FIG. 11, the first groove 300 of the substrate SUB may be formed in a form in which the first groove 300 does not completely pass through the second substrate SUB2 and the second substrate SUB is recessed.

FIG. 12 is a cross-sectional view of another bezel area (e.g., a first non-display area NDA1) having a narrow bezel structure and moisture penetration preventing structure in a display panel 110 according to embodiments of the present disclosure. In the following description, reference is made also to FIG. 3.

As shown in FIGS. 5 to 11, the first groove 300 may be formed in only some (e.g., the second to fourth non-display areas NDA2 to NDA4) of the non-display areas NDA.

Unlike this, as shown in FIG. 12, the first groove 300 may not be formed in the non-display area NDA between the pad area PA and the display area DA among the non-display areas NDA, that is, the first non-display area NDA1.

As described above, the non-display area NDA may include the first non-display area NDA1 which is located outside the display area DA in the first direction, the second non-display area NDA2 which is located outside the display area DA in the second direction different from the first direction, the third non-display area NDA3 which is located outside the display area DA in the direction opposite to the first direction, and the fourth non-display area NDA4 which is located outside the display area DA in the direction opposite to the second direction.

As shown in FIGS. 5 to 11, the first groove 300 may be present in the second non-display area NDA2, the third non-display area NDA3 and the fourth non-display area NDA4, and as shown in FIG. 12, the first groove 300 may not be present in the entirety or a part of the first non-display area NDA1.

As illustrated in FIG. 12, a pad 800 may be disposed in the first non-display area NDA1. At least one insulating layer among the second inorganic layer 520, the third inorganic layer 530 and the touch insulating layer 550 may be disposed on at least a portion of the pad 800.

A brief description of the embodiments of the present disclosure described above is as follows.

A display device according to embodiments of the present disclosure may include a substrate including a display area in which a plurality of subpixels are disposed and a non-display area which is located outside the display area and includes a pad area, and having a first groove in the non-display area; a first inorganic layer disposed on the substrate, extending from the display area to the non-display area, and having a second groove which is located in the non-display area to be closer to the display area than the first groove; an organic layer disposed on a portion of the first inorganic layer in the non-display area, and filling the second groove; a second inorganic layer extending from the display area to the non-display area, disposed on the first inorganic layer to cover the organic layer, and extending to the inside of the first groove; and a third inorganic layer extending from the display area to the non-display area, disposed on the second inorganic layer, and extending to the inside of the first groove.

The display device according to the embodiments of the present disclosure may further include a touch insulating layer extending from the display area to the non-display area, disposed on the third inorganic layer, and overlapping the organic layer.

The first inorganic layer may include at least one inorganic layer for forming a transistor.

The display device according to the embodiments of the present disclosure may further include a light emitting element disposed between the first inorganic layer and the second inorganic layer in the display area; and an encapsulation layer on the light emitting element. The second inorganic layer and the third inorganic layer may be included in the encapsulation layer.

The display device according to the embodiments of the present disclosure may further include a touch bridge metal disposed on the encapsulation layer; a touch sensor metal disposed on the touch bridge metal; and a touch interlayer insulating layer disposed between the touch bridge metal and the touch sensor metal. The touch insulating layer may include the touch interlayer insulating layer.

The display device according to the embodiments of the present disclosure may further include a touch buffer layer disposed between the encapsulation layer and the touch bridge metal. The touch insulating layer may further include the touch buffer layer.

The touch insulating layer may extend to the inside of the first groove.

In the display device according to the embodiments of the present disclosure, the first inorganic layer may include a first insulating layer on the substrate; and a second insulating layer on the first insulating layer. The second groove may correspond to a hole or a groove which is formed in the second insulating layer.

The display device according to the embodiments of the present disclosure may further include a blocking metal disposed on the first insulating layer.

Both ends of the blocking metal may be located between the first insulating layer and the second insulating layer, and a portion between both the ends of the blocking metal may overlap the second groove.

The display device according to the embodiments of the present disclosure may further include a transistor disposed in the display area; and a shield metal disposed under the transistor. The blocking metal may be disposed at the same layer as the shield metal.

The display device according to the embodiments of the present disclosure may further include at least one metal layer disposed between the first inorganic layer and the second inorganic layer, and extending from the display area to the non-display area.

The at least one metal layer may extend to the inside of the second groove of the first inorganic layer.

The display device according to the embodiments of the present disclosure may further include a planarization layer disposed between the first inorganic layer and the second inorganic layer; a light emitting element disposed on the planarization layer; and a bank disposed on the planarization layer, and defining a light emitting area of the light emitting element.

The organic layer may include the planarization layer.

The organic layer may further include the bank.

The organic layer may further include a spacer on the bank.

In the display device according to the embodiments of the present disclosure, the substrate may include a first substrate; an intermediate insulating layer on the first substrate; and a second substrate on the intermediate insulating layer.

The first groove may be formed in the second substrate. In detail, the first groove may be formed in only the second substrate, and may not be formed in the intermediate insulation layer and the first substrate.

In the display device according to the embodiments of the present disclosure, the first groove may be formed in only a portion of the non-display area, and the first groove may not be formed between the pad area in the non-display area and the display area.

For example, in the display device according to the embodiments of the present disclosure, the non-display area may include a first non-display area located outside the display area in a first direction; a second non-display area located outside the display area in a second direction different from the first direction; a third non-display area located outside the display area in a direction opposite to the first direction; and a fourth non-display area located outside the display area in a direction opposite to the second direction.

For example, the first groove may be present in the second non-display area, the third non-display area and the fourth non-display area, and the first groove may not be present in entirety or a part of the first non-display area.

A display device according to embodiments of the present disclosure may include a substrate including a display area in which an image is displayed and a non-display area as an area outside the display area, and having a first groove in the non-display area; a first inorganic layer disposed on the substrate, extending from the display area to the non-display area, and having a second groove which is located in the non-display area to be closer to the display area than the first groove; a planarization layer on the first inorganic layer; an organic layer disposed on a portion of the first inorganic layer in the non-display area, and filling the second groove; a light emitting element on the planarization layer; a first inorganic encapsulation layer on the light emitting element; an organic encapsulation layer on the first inorganic encapsulation layer; and a second inorganic encapsulation layer on the organic encapsulation layer.

The first inorganic encapsulation layer may extend from the display area to the non-display area, may be disposed on the first inorganic layer to cover the organic layer, and may extend to the inside of the first groove.

The second inorganic encapsulation layer may extend from the display area to the non-display area, may be disposed on the second inorganic layer, and may extend to the inside of the first groove.

The display device according to the embodiments of the present disclosure may further include a touch insulating layer extending from the display area to the non-display area, disposed on the second inorganic encapsulation layer, and overlapping the organic layer.

The display device according to the embodiments of the present disclosure may further include a touch bridge metal disposed on the second inorganic encapsulation layer; a touch sensor metal disposed on the touch bridge metal; and a touch interlayer insulating layer disposed between the touch bridge metal and the touch sensor metal. The touch insulating layer may include the touch interlayer insulating layer.

The display device according to the embodiments of the present disclosure may further include a touch buffer layer disposed between the encapsulation layer and the touch bridge metal. The touch insulating layer may further include the touch buffer layer.

In the display device according to the embodiments of the present disclosure, the touch insulating layer may extend to the inside of the first groove of the substrate.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the technical features of the present disclosure by way of example and are not intended to limit the scope of the present disclosure.

What is claimed is:

1. A display device, comprising:
a substrate including a display area in which a plurality of subpixels are disposed and a non-display area which is located outside the display area and includes a pad area, and having a first groove in the non-display area;
a first inorganic layer disposed on the substrate, extending from the display area to the non-display area, and having a second groove which is located in the non-display area to be closer to the display area than the first groove;
an organic layer disposed on a portion of the first inorganic layer in the non-display area, and filling the second groove;
a second inorganic layer extending from the display area to the non-display area, disposed on the first inorganic layer to cover the organic layer, and extending to the inside of the first groove; and
a third inorganic layer extending from the display area to the non-display area, disposed on the second inorganic layer, and extending to the inside of the first groove.

2. The display device of claim 1, further comprising:
a touch insulating layer extending from the display area to the non-display area, disposed on the third inorganic layer, and overlapping the organic layer.

3. The display device of claim 2, wherein the first inorganic layer includes at least one inorganic layer for forming a transistor.

4. The display device of claim 2, further comprising:
a light emitting element disposed between the first inorganic layer and the second inorganic layer in the display area; and
an encapsulation layer on the light emitting element,
wherein the second inorganic layer and the third inorganic layer are included in the encapsulation layer.

5. The display device of claim 4, further comprising:
a touch bridge metal disposed on the encapsulation layer;
a touch sensor metal disposed on the touch bridge metal; and
a touch interlayer insulating layer disposed between the touch bridge metal and the touch sensor metal,
wherein the touch insulating layer includes the touch interlayer insulating layer.

6. The display device of claim 5, further comprising:
a touch buffer layer disposed between the encapsulation layer and the touch bridge metal,
wherein the touch insulating layer further includes the touch buffer layer.

7. The display device of claim 2, wherein the touch insulating layer extends to the inside of the first groove.

8. The display device of claim 1,
wherein the first inorganic layer comprises:
a first insulating layer on the substrate; and
a second insulating layer on the first insulating layer, and
wherein the second groove corresponds to a hole or a groove which is formed in the second insulating layer.

9. The display device of claim 8, further comprising:
a blocking metal disposed on the first insulating layer,
wherein both ends of the blocking metal are located between the first insulating layer and the second insulating layer, and a portion between both the ends of the blocking metal overlaps the second groove.

10. The display device of claim 9, further comprising:
a transistor disposed in the display area; and
a shield metal disposed under the transistor,
wherein the blocking metal is disposed at the same layer as the shield metal.

11. The display device of claim 1, further comprising:
at least one metal layer disposed between the first inorganic layer and the second inorganic layer, and extending from the display area to the non-display area,
wherein the at least one metal layer extends to the inside of the second groove of the first inorganic layer.

12. The display device of claim 1, further comprising:
a planarization layer disposed between the first inorganic layer and the second inorganic layer;
a light emitting element disposed on the planarization layer; and
a bank disposed on the planarization layer, and defining a light emitting area of the light emitting element,
wherein the organic layer includes the planarization layer.

13. The display device of claim 12, wherein the organic layer further includes the bank.

14. The display device of claim 13, further comprising:
a spacer on the bank,
wherein the organic layer further includes the spacer.

15. The display device of claim 1,
wherein the substrate comprises:
a first substrate;
an intermediate insulating layer on the first substrate; and
a second substrate on the intermediate insulating layer, and
wherein the first groove is formed in the second substrate.

16. The display device of claim 15, wherein the first groove is formed in only the second substrate and is not formed in the first substrate.

17. The display device of claim 1, wherein:
the first groove is formed in only a portion of the non-display area, and
the first groove is not formed between the pad area in the non-display area and the display area.

18. The display device of claim 1,
wherein the non-display area comprises:
a first non-display area located outside the display area in a first direction;
a second non-display area located outside the display area in a second direction different from the first direction;
a third non-display area located outside the display area in a direction opposite to the first direction; and
a fourth non-display area located outside the display area in a direction opposite to the second direction,
wherein the first groove is present in the second non-display area, the third non-display area and the fourth non-display area, and
wherein the first groove is not present in entirety or a part of the first non-display area.

19. A display device, comprising:
a substrate including a display area in which an image is displayed and a non-display area as an area outside the display area, and having a first groove in the non-display area;
a first inorganic layer disposed on the substrate, extending from the display area to the non-display area, and having a second groove which is located in the non-display area to be closer to the display area than the first groove;
a planarization layer on the first inorganic layer;
an organic layer disposed on a portion of the first inorganic layer in the non-display area, and filling the second groove;
a light emitting element on the planarization layer;
a first inorganic encapsulation layer on the light emitting element;
an organic encapsulation layer on the first inorganic encapsulation layer; and
a second inorganic encapsulation layer on the organic encapsulation layer,
wherein the first inorganic encapsulation layer extends from the display area to the non-display area, is disposed on the first inorganic layer to cover the organic layer, and extends to the inside of the first groove, and
wherein the second inorganic encapsulation layer extends from the display area to the non-display area, is disposed on the second inorganic layer, and extends to the inside of the first groove.

20. The display device of claim 19, further comprising:
a touch insulating layer extending from the display area to the non-display area, disposed on the second inorganic encapsulation layer, and overlapping the organic layer.

21. The display device of claim 20, further comprising:
a touch bridge metal disposed on the second inorganic encapsulation layer;
a touch sensor metal disposed on the touch bridge metal; and
a touch interlayer insulating layer disposed between the touch bridge metal and the touch sensor metal,
wherein the touch insulating layer includes the touch interlayer insulating layer.
